(19) United States
(12) Patent Application Publication
(10) Pub. No.: US 2025/0238572 A1
(43) Pub. Date: Jul. 24, 2025

(54) SYSTEM AND METHOD FOR MANAGING COMPONENTS OF A VEHICLE SYSTEM

(71) Applicant: WOVEN BY TOYOTA, INC., Tokyo (JP)

(72) Inventors: Jean-François BASTIEN, Tokyo (JP); Jean-Francois CAMPEAU, Tokyo (JP); Daniel HEBBERD, Tokyo (JP); Kentaro SHIOTA, Tokyo (JP)

(73) Assignee: WOVEN BY TOYOTA, INC., Tokyo (JP)

(21) Appl. No.: 18/421,184

(22) Filed: Jan. 24, 2024

(51) Int. Cl. G06F 30/20; G06F 30/15

(52) U.S. Cl. CPC G06F 30/20; G06F 30/15

(57) ABSTRACT

Provided are a method and a system for managing components in vehicle systems. The method may include: receiving, from a first user, a first user input associated with selection of at least one of a single vehicle model, a single variant of the single vehicle model, a plurality of vehicle models, a single variant of the plurality of vehicle models, and a plurality of variants of the plurality of vehicle models; receiving, from the first user, a second user input associated with configuration of a simulation environment; determining, based on the first user input and the second user input, a plurality of hardware components and a plurality of software components; building a virtual vehicle network by interconnecting the plurality of hardware and software components; and performing the first operation on the virtual vehicle network to manage the first portion of the hardware components and the software components.

### TECHNICAL FIELD

Systems and methods consistent with example embodiments of the present disclosure relate to a vehicle system, and more particularly, relate to managing components of a vehicle system.

### BACKGROUND

The automotive industry is facing challenges in components management, due to the increasing number of vehicle models and vehicle variants within each model. This results in a significant amount of time, cost, and resources required for components management, including software components development and testing.

To begin with, in the related art, the designs of physical hardware components and software components of a vehicle are performed separately, and the designs of said components are not incorporated into the development process of the vehicle, but are only being used as reference materials. Further, during the development process of the vehicle, the software components are built on specific hardware components, which makes it difficult to allow for separate testing or early testing before the hardware components are available.

Furthermore, in the related art, software development processes involve physically interfacing with physical hardware components (e.g., built vehicles or prototypes), which can be expensive and time-consuming. For instance, a vendor or a supplier is required to physically visit a testing facility of a vehicle manufacturer, where the prototype, production hardware, underlying systems, and the like, are deployed. This often involves traveling to different regions, and scheduling a time for utilizing the testing facility. Further, the number of resources in the testing facility may be limited, and thus the number of processes which can simultaneously be performed at the testing facility may be limited.

In addition, in the related art, the variation of hardware components and software components may be limited within a single vehicle model and/or vehicle variant. In this regard, many vehicle manufacturers have significant amount of vehicle models and multiple vehicle variants per vehicle model. These vehicle models and variants necessitate software development, testing, and updating, prior to deploying the software to the vehicle. Accordingly, software creating, testing, and updating is complex, time consuming, and costly.

Further, in the related art, it is difficult to manage (e.g., create, test, deploy, etc.) the software components via Over-the-Air (OTA) across multiple vehicle models and vehicle variants. This is because, in order to perform OTA management, the vehicle manufacturer would have to have exact replicas of all vehicle models and variants.

In view of the above, there is a need for a more efficient and cost-effective method to develop, test, and update components in the vehicle system.

### SUMMARY

Example embodiments of the present disclosure provide methods, systems, and apparatuses for effectively and efficiently managing one or more components in one or more vehicle systems.

According to embodiments, a method for managing components of a vehicle system is provided. The method may be implemented by at least one processor of a system and may include: receiving, from a first user, a first user input associated with selection of at least one of a single vehicle model, a single variant of the single vehicle model, a plurality of vehicle models, a single variant of the plurality of vehicle models, and a plurality of variants of the plurality of vehicle models; receiving, from the first user, a second user input associated with configuration of a simulation environment; determining, based on the first user input and the second user input, a plurality of hardware components and a plurality of software components associated with the first user input and the second user input; building a virtual vehicle network by interconnecting the plurality of hardware components and the plurality of software components, wherein the virtual vehicle network comprises the interconnection of the components of the vehicle system; receiving, from the first user, a third user input associated with a first operation for managing a first portion of the hardware components and the software components in the virtual vehicle network; and performing, based on the third user input, the first operation on the virtual vehicle network to manage the first portion of the hardware components and the software components.

According to embodiments, the method may further include: receiving, from a second user, a fourth user input for selecting the virtual vehicle network; receiving, from the second user, a fifth user input associated with a second operation for managing a second portion of the hardware components and the software components in the virtual vehicle network; and performing, based on the fifth user input, the second operation on the virtual vehicle network to manage the second portion of the hardware components and the software components. The second operation may be different from the first operation, and the second portion may be different from the first portion.

According to embodiments, at least a portion of the plurality of hardware components, the plurality of software components, or a combination thereof, may be located at different geographical locations. Additionally or alternatively, at least a portion of the plurality of hardware components, the plurality of software components, or a combination thereof, may be associated with users different from the first user. The plurality of hardware components may include: a plurality of production hardware, a plurality of prototype hardware, or a combination thereof. The plurality of software components may include: a plurality of production software, a plurality of prototype software, a plurality of virtual hardware, or a combination thereof.

According to embodiments, at least a portion of the plurality of hardware components and at least a portion of the plurality of software components are located at different geographical locations, and the building the virtual vehicle network may include: building, based on the plurality of hardware components and the plurality of software components located at different geographical locations, at least one virtual vehicle replica; building at least one simulation model; and interconnecting the at least one virtual vehicle replica to the at least one simulation model to build the virtual vehicle network.

According to embodiments, the building the at least one virtual vehicle replica may include: obtaining a connection configuration information; creating, based on the connection configuration information, a virtual network; and interconnecting the plurality of hardware components and the plurality of software components located at different geographical locations with the virtual network. The interconnecting the plurality of hardware components and the plurality of software components may include: deploying the plurality of software components in one or more devices communicatively coupled to the system; reserving the plurality of hardware components; and interconnecting the one or more devices and the reserved hardware components.

According to embodiments, the building the at least one simulation model may include: obtaining, based on the second user input, at least one operational model and at least one conditional model; and interconnecting the at least one operational model and the at least one conditional model to build the at least one simulation model. The at least operational model may include information defining vehicle dynamics, vehicle kinematics, and vehicle control. The at least one conditional model may include information defining a road condition, a weather condition, a traffic condition, and an event.

According to embodiments, the performing the one or more actions may include performing at least one of: sharing, to one or more users different from the first user, at least a portion the virtual vehicle network; designing, by arranging the at least one virtual vehicle replica, a vehicle; designing, by arranging the at least one simulation model, a test scenario; and testing a software component in the virtual vehicle network.

According to embodiments, a system for managing components of a vehicle system is provided. The system may include a memory storage storing computer-executable instructions and at least one processor communicatively coupled to the memory storage. The at least one processor may be configured to execute the instructions to: receive, from a first user, a first user input associated with selection of at least one of: a single vehicle model, a single variant of the single vehicle model, a plurality of vehicle models, a single variant of the plurality of vehicle models, and a plurality of variants of the plurality of vehicle models; receive, from the first user, a second user input associated with configuration of a simulation environment; determine, based on the first user input and the second user input, a plurality of hardware components and a plurality of software components associated with the first user input and the second user input; build a virtual vehicle network by interconnecting the plurality of hardware components and the plurality of software components, the virtual vehicle network may include the interconnection of the components of the vehicle system; receive, from the first user, a third user input associated with a first operation for managing a first portion of the hardware components and the software components in the virtual vehicle network; and perform, based on the third user input, the first operation on the virtual vehicle network to manage the first portion of the hardware components and the software components.

According to embodiments, the at least one processor may be further configured to execute the instructions to: receive, from a second user, a fourth user input for selecting the virtual vehicle network; receive, from the second user, a fifth user input associated with a second operation for managing a second portion of the hardware components and the software components in the virtual vehicle network; and perform, based on the fifth user input, the second operation on the virtual vehicle network to manage the second portion of the hardware components and the software components. The second operation may be different from the first operation, and the second portion may be different from the first portion.

According to embodiments, at least a portion of the plurality of hardware components, the plurality of software components, or a combination thereof, may be located at different geographical locations. Additionally or alternatively, at least a portion of the plurality of hardware components, the plurality of software components, or a combination thereof, may be associated with users different from the first user. The plurality of hardware components may include: a plurality of production hardware, a plurality of prototype hardware, or a combination thereof. The plurality of software components may include: a plurality of production software, a plurality of prototype software, a plurality of virtual hardware, or a combination thereof.

According to embodiments, at least a portion of the plurality of hardware components and at least a portion of the plurality of software components may be located at different geographical locations, and the at least one processor may be configured to execute the instructions to build the virtual vehicle network by: building, based on the plurality of hardware components and the plurality of software components located at different geographical locations, at least one virtual vehicle replica; building at least one simulation model; and interconnecting the at least one virtual vehicle replica to the at least one simulation model to build the virtual vehicle network. The at least one processor may be configured to execute the instructions to build the at least one virtual vehicle replica by: obtaining a connection configuration information; creating, based on the connection configuration information, a virtual network; and interconnecting the plurality of hardware components and the plurality of software components located at different geographical locations with the virtual network. The at least one processor may be configured to execute the instructions to interconnect the plurality of hardware components and the plurality of software components by: deploying the plurality of software components in one or more devices communicatively coupled to the system; reserving the plurality of hardware components; and interconnecting the one or more devices and the reserved hardware components.

According to embodiments, the at least one processor may be configured to execute the instructions to build the at least one simulation model by: obtaining, based on the second user input, at least one operational model and at least one conditional model; and interconnecting the at least one operational model and the at least one conditional model to build the at least one simulation model. The at least operational model may include information defining vehicle dynamics, vehicle kinematics, and vehicle control. The at least one conditional model may include information defining a road condition, a weather condition, a traffic condition, and an event.

According to embodiments, the at least one processor may be configured to execute the instructions to perform the one or more actions by performing at least one of: sharing, to one or more users different from the first user, at least a portion the virtual vehicle network; designing, by arranging the at least one virtual vehicle replica, a vehicle; designing, by arranging the at least one simulation model, a test scenario; and testing a software component in the virtual vehicle network.

Additional aspects will be set forth in part in the description that follows and, in part, will be apparent from the description, or may be realized by practice of the presented embodiments of the disclosure.

### BRIEF DESCRIPTION OF THE DRAWINGS

Features, advantages, and significance of exemplary embodiments of the disclosure will be described below with reference to the accompanying drawings, in which like reference numerals denote like elements, and wherein:

FIG. 1 illustrates a block diagram of an example system architecture for managing components of a vehicle system, according to one or more embodiments;

FIG. 2 illustrates a block diagram of example components of a components management system, according to one or more embodiments;

FIG. 3 illustrates a flow diagram of an example method for managing components of a vehicle system, according to one or more embodiments; and

FIG. 4, which illustrates an example system architecture including a virtual vehicle network, according to one or more embodiments.

### DETAILED DESCRIPTION

The following detailed description of exemplary embodiments refers to the accompanying drawings. The foregoing disclosure provides illustration and description but is not intended to be exhaustive or to limit the implementations to the precise form disclosed. Modifications and variations are possible in light of the above disclosure or may be acquired from practice of the implementations. Further, one or more features or components of one embodiment may be incorporated into or combined with another embodiment (or one or more features of another embodiment). Additionally, in the flowcharts and descriptions of operations provided below, it is understood that one or more operations may be omitted, one or more operations may be added, one or more operations may be performed simultaneously (at least in part), and the order of one or more operations may be switched.

Even though particular combinations of features are recited in the claims and/or disclosed in the specification, these combinations are not intended to limit the disclosure of possible implementations. In fact, many of these features may be combined in ways not specifically recited in the claims and/or disclosed in the specification. Although each dependent claim listed below may directly depend on only one claim, the disclosure of possible implementations includes each dependent claim in combination with every other claim in the claim set.

No element, act, or instruction used herein should be construed as critical or essential unless explicitly described as such. Also, as used herein, the articles “a” and “an” are intended to include one or more items, and may be used interchangeably with “one or more.” Where only one item is intended, the term “one” or similar language is used. Also, as used herein, the terms “has,” “have,” “having,” “include,” “including,” or the like are intended to be open-ended terms. Further, the phrase “based on” is intended to mean “based, at least in part, on” unless explicitly stated otherwise. Furthermore, expressions such as “at least one of [A] and [B]” or “at least one of [A] or [B]” are to be understood as including only A, only B, or both A and B.

Reference throughout this specification to “one embodiment,” “an embodiment,” “non-limiting exemplary embodiment,” or similar language means that a particular feature, structure, or characteristic described in connection with the indicated embodiment is included in at least one embodiment of the present solution. Thus, the phrases “in one embodiment”, “in an embodiment,” “in one non-limiting exemplary embodiment,” and similar language throughout this specification may, but do not necessarily, all refer to the same embodiment.

Furthermore, the described features, advantages, and characteristics of the present disclosure may be combined in any suitable manner in one or more embodiments. One skilled in the relevant art will recognize, in light of the description herein, that the present disclosure can be practiced without one or more of the specific features or advantages of a particular embodiment. In other instances, additional features and advantages may be recognized in certain embodiments that may not be present in all embodiments of the present disclosure.

In addition, the term “vehicle” or the like, as used herein, may refer to any motorized and/or mechanical machine which may carry or transport people and/or cargo, such as: a car, a truck, a motorcycle, a bus, a bicycle, a mobility scooter, and the like.

Descriptions of example embodiments of present disclosure are provided in the following.

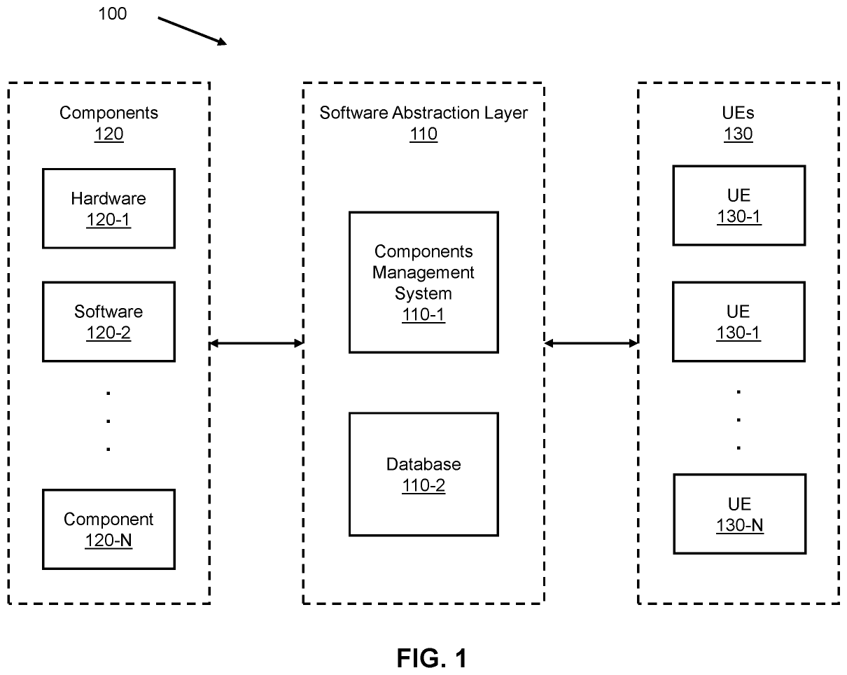

FIG. 1 illustrates a block diagram of an example system architecture 100 for managing components of a vehicle system, according to one or more embodiments. As illustrated in FIG. 1, system architecture 100 may include a software abstraction layer 110 communicatively coupling a plurality of components 120 to a plurality of user equipment (UEs) 130. In general, a plurality of users associated with the plurality of UEs 130 may utilize the plurality of UEs 130 to manage the plurality of components 120 via the software abstraction layer 110.

The software abstraction layer may bridge or interconnect different components located at different geographical locations and/or associated with different users, thereby providing centralized management of components for multiple locations and/or associated with multiple users via a single abstraction layer. By leveraging the software abstraction layer, example embodiments of present disclosure enable multiple users to effectively and efficiently manage components of a vehicle system, without requiring the users to have expertise on all components of the vehicle system, and mitigate the requirement for physical travelling to the site at which the components are deployed.

Further, by leveraging the software abstraction layer, example embodiments of present disclosure enable the substitution of components while maintaining the integrity of the component management processes. Furthermore, example embodiments allow the underlying components to be of variable levels of abstractions. Ultimately, example embodiments may provide a hybrid vehicle network system which leverages the advantages of high fidelity of physical, hardware components and the cost effectiveness of virtual, software components.

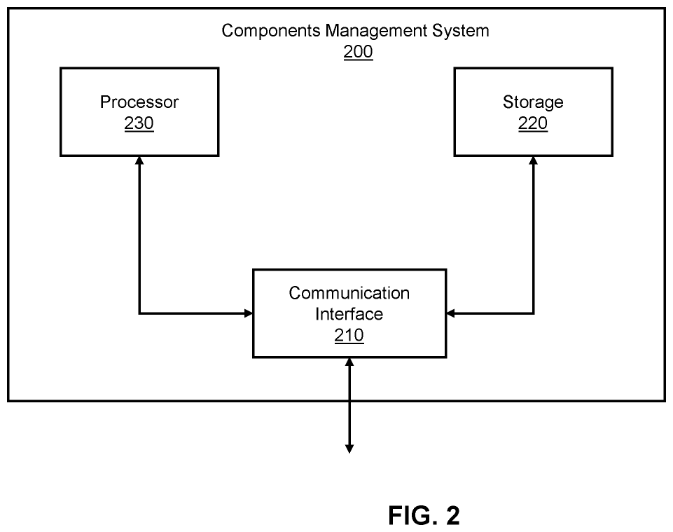

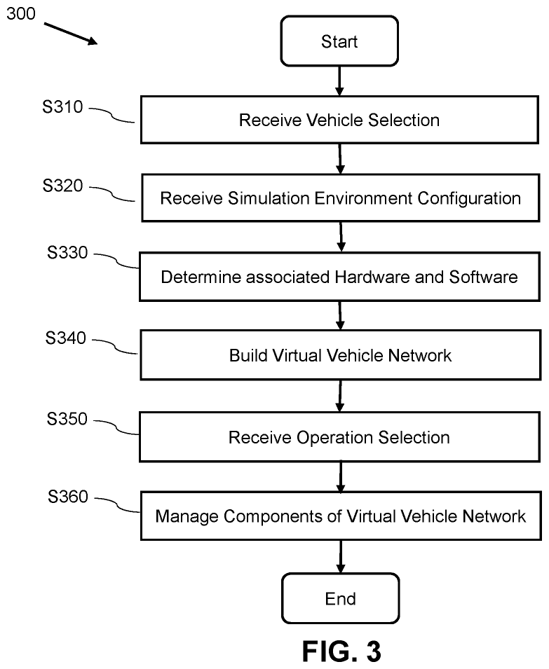

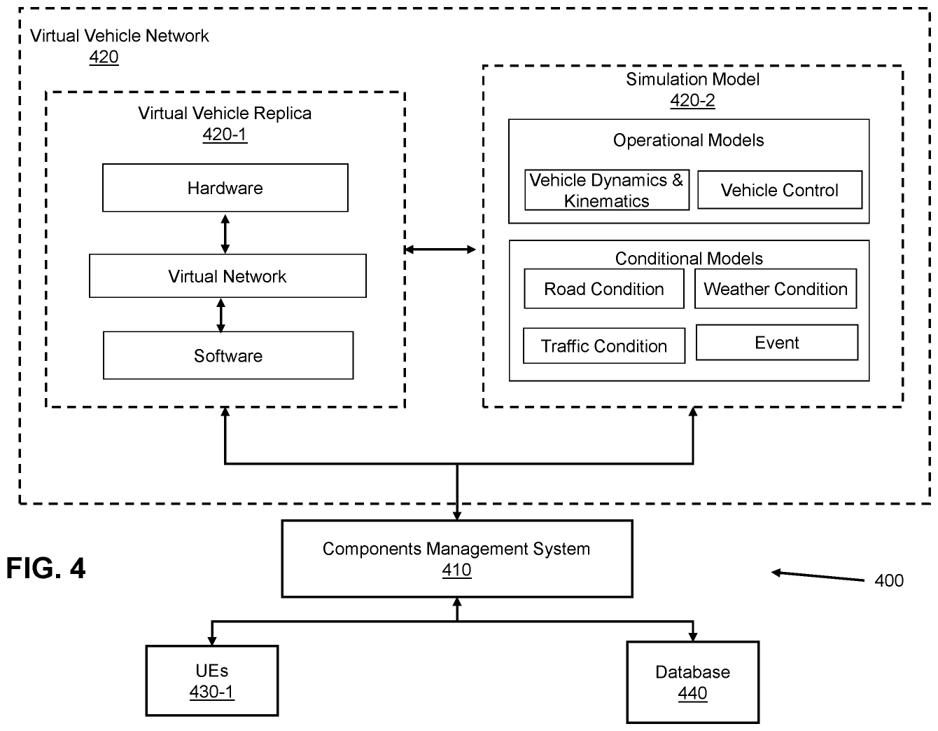

As illustrated in FIG. 1, the software abstraction layer 100 may include a components management system 110-1 and at least one database 110-2. Descriptions of the components which may be included in the components management system 110-1 are provided below with reference to FIG. 2. Further, descriptions of operations which may be performed by the components management system 110-1, as well as example use case associated therewith, are provided below with reference to FIG. 3 and FIG. 4.

The database 110-2 may include one or more of a server, a repository, or any suitable equipment which may be configured to store and provide data or information. According to embodiments, the database 110-2 may leverage indexing and querying functionalities of database (e.g., SQL, scalable graph database, etc.) in storing and provisioning of data and information. According to embodiments, the database 110-2 may be configured to store and provide data or information in real-time or near real-time.

The information which may be stored and provided by the database 110-2 may include (but are not limited to) information associated with: hardware components, software components, vehicle models, vehicle variants, virtual vehicle network, and any other suitable data or information.

In this regard, the “hardware components” described herein may refer to fully developed, partially developed, and/or prototype physical components in a vehicle, such as (but are not limited to): physical electronic control units (ECUs), transmission control units (TCUs), actuators in the vehicle, sensors in the vehicle, vehicle engine, vehicle seats, vehicle gears, vehicle telematics devices, and the like. In this regard, the information associated with the hardware components may include (but are not limited to): function of each hardware component, type of each hardware component, location at which each hardware component is deployed, user associated with each hardware component, availability of each hardware component, information of software associated with each hardware component (if any), vehicle model(s) and vehicle variant(s) which involve each hardware component, and the like.

The “software components” described herein may refer to fully developed, partially developed, and/or prototype virtual components of the vehicle, such as (but are not limited to): software applications like operational system (OS) of a system (e.g., infotainment system, driving assistance system, etc.) in the vehicle, virtualized and/or emulated ECUs, simulated hardware, and the like. In addition, the “software components” described herein may also refer to computer-executable software models, such as operational model for simulating operational conditions of the vehicle and conditional models for simulating environmental conditions of the vehicle. In this regard, the information associated with the software components may include (but are not limited to): function of each software component, type of each software component, version of each software component, information of storage storing or hosting each software component, programming codes or algorithms of the software component, information of hardware associated with each software component (if any), resource requirements for deploying each software component, vehicle model(s) and vehicle variant(s) which involve each software component, information of virtual vehicle network which involve each software component, and the like.

The “vehicle models” described herein may refer to a specific lineup, version, and/or type of vehicles produced by a vehicle manufacturer. Each vehicle model may be characterized by a unique set of features, specifications, design elements, and the like, that differentiate itself from other models within the same/different vehicle manufacturer. Further, vehicle models may be designed according to usage purpose (e.g., sedans, trucks, sport car, electric vehicle, etc.) and may be identified by a specific name/designation which represents a distinct or recognizable characteristics. In this regard, the information associated with the vehicle model may include (but are not limited to): information of users (e.g., vendor, supplier, etc.) associated with components involved in each vehicle model, features/specifications of each vehicle model, information of vehicle variants associated with each vehicle model, usage purpose of each vehicle model, name/designation of each vehicle model, information of hardware components involved in each vehicle model, information of software components involved in each vehicle model, information of a vehicle specification or a vehicle manual, and the like.

The terms “vehicle variants” described herein may refer to trim levels or different versions of a specific vehicle model, each of which may offer various combinations of hardware components and software components to provide different features and specifications, while maintaining the main design of the specific vehicle model. By way of example, the vehicle variants may be categorized according to type of vehicle propulsion system (e.g., pure gasoline, diesel, hybrid, pure electric, etc.), type of vehicle drivetrain system (e.g., Front-Wheel Drive (FWD), Rear-Wheel Drive (RWD), Four-Wheel Drive (4WD), etc.), vehicle trim level (e.g., basic, standard, sports, luxury), and the like. In this regard, the information associated with the vehicle variant may include (but are not limited to): information of features of each vehicle variant, information of hardware components and software components associated with each vehicle variant, information of vehicle model associated with each vehicle variant, name/designation of each vehicle variant, information of configuration for connecting the hardware components and the software components in each vehicle variant (may be referred to as “connection configuration” herein), and the like.

The terms “virtual vehicle network” described herein may refer to a representation of interconnection and relationship among the components of a user-intended vehicle system. In other words, the virtual vehicle network may define a high fidelity, dynamic, and customizable communication infrastructure which represents the connections between the plurality of hardware components and the plurality of software components of the user-intended vehicle model(s) (and vehicle variant(s), if any) and the user-defined simulation environment configuration. As further described below with reference to FIG. 3 and FIG. 4, a virtual vehicle network may consist of at least one virtual vehicle replica and at least one simulation model. In this regard, the terms “virtual vehicle replica” described herein may refer to a representation of interconnection and relationship among the hardware components and the software components of the user-intended vehicle model (and vehicle variant, if any). On the other hand, the terms “simulation model” described herein may refer to combination of software models which define a virtual environment in which the virtual vehicle replica can be simulated. Specifically, the simulation model may define environment configurations for simulating one or more user-intended conditions and scenarios. According to embodiments, the simulation model may include one or more operational models and one or more conditional models. The one or more operational models may include information defining operational configuration, such as vehicle dynamics information for simulating forces (e.g., aerodynamic forces, tire forces, gravity, inertial forces, etc.) acting on vehicle components (e.g., chassis, suspension system, tires, powertrain, etc.), vehicle kinematics information for simulating motion and geometric relationship (e.g., position, velocity, wheel motion, steering angles, etc.) among the vehicle components, vehicle control information for simulating control algorithms or operations in governing vehicle functionalities (e.g., stability control anti-lock braking (ABS) control, electronic stability control (ESC), etc.), and the like. The one or more conditional models may include information defining environmental conditions, such as a road condition, a weather condition, a traffic condition, an event, and the like. Further descriptions of the virtual vehicle network, virtual vehicle replica, and simulation model, are provided below with reference to FIG. 3 and FIG. 4.

In this regard, the information associated with the virtual vehicle network may include (but are not limited to): information of hardware components and software components constituting the virtual vehicle replica(s) in the virtual vehicle network, such as the connection configuration of the hardware components and the software components in the virtual vehicle replica, connection configuration of the virtual vehicle replica and the simulation model, the users associated with the virtual vehicle network (e.g., creator, editor, manager, etc.), sharing setting of the virtual vehicle network, logs of historical operations involved the virtual vehicle network, and the like. According to embodiments, the information of the virtual vehicle network may be stored in a configuration file which is shareable and executable across multiple systems and user devices.

Referring still to FIG. 1, the plurality of components 120 may include a plurality of hardware components 120-1, a plurality of software components 120-2, and any other suitable components which constitute a vehicle system. The descriptions associated with “hardware components” and “software components” are provided above with reference to database 110-2, thus redundant descriptions associated therewith may be omitted below for conciseness.

According to embodiments, at least a portion of the components 120 may be located at different geographical locations. For instance, a portion of the hardware components 120-1 may be located at a first location and another portion of the hardware components 120-1 may be located at a second location, where the first location is different from the second location. Similarly, a portion of the software components 120-2 may be located/deployed at geographical location(s) different from another portion of the software components 120-2, a portion of the hardware components 120-1 may be located at geographical location(s) different from a portion of the software components 120-2, and the like.

On the other hand, the plurality of UEs 120-1 to 120-N may include one or more systems, devices, and any other suitable equipment which may be utilized by one or more users associated with one or more of the components 120. The one or more users may include, but are not limited to, a software developer for developing a software component, a manager of one or more components from among the components 120, a vehicle manufacturer, a vendor, a supplier, and the like. The one or more users may be located at different geographical locations.

The plurality of UEs 130-1 to 130-N may be utilized by one or more associated users to access and to utilize the components management system 110. Specifically, the user(s) may access, via the associated UE, the components management system 110 to manage the one or more components. For instance, the user(s) may utilize, via the associated UE, the components management system 110 to build a virtual vehicle network, to share at least a portion of the built virtual vehicle network with one or more hardware components and/or one or more software components, to utilize the built virtual vehicle network to design a vehicle, to utilize the built virtual vehicle network to design a test scenario, to perform a testing on a software component in the virtual vehicle network, and the like. According to embodiments, multiple users may utilize the associated UE to simultaneously access the components management system 110-1 to simultaneously or sequentially perform one or more operations for managing the components of the vehicle system.

According to embodiments, one or more of the plurality of UEs 120-1 to 120-N may include a computing device (e.g., a desktop computer, a laptop computer, a tablet computer, a handheld computer, a smart speaker, a server, etc.), a mobile device (e.g., a smart phone, etc.), a wearable device (e.g., a pair of smart glasses or a smart watch), a SIM-based device, or any other suitable device which may be associated with the one or more users. Further, the plurality of UEs 120-1 to 120-N may include, for example, a work station, a testing system associated with one or more test environments, a software development system, and the like.

According to embodiments, at least a portion of the plurality of UEs 120-1 to 120-N may be located at different geographical locations. For instance, a first portion of the plurality of UEs 120-1 to 120-N may be utilized by a first user (e.g., a developer of a software component, etc.) and the first user and the associated UE(s) may locate at a first location, while a second portion of the plurality of UEs 120-1 to 120-N may be utilized by a second user (e.g., a manager of a hardware component, etc.) and the second user and the associated UE(s) may locate at a second location different from the first location.

According to embodiments, one or more components of the system architecture 100 may be implemented in a cloud environment. For instance, at least a portion of the software components 120-2 may be defined in computer-executable instances and may be hosted in a plurality of cloud servers (e.g., public cloud, private cloud, hybrid cloud, etc.). As another example, one or more operations of components management system 110-1 may be defined in computer-executable instructions and may be hosted in the plurality of cloud servers.

According to embodiments, the components of the system architecture 100 may be communicatively coupled to one another via one or more networks (e.g., wireless network, wired network, or a combination thereof). For instance, the one or more networks may include a cellular network (e.g., a fifth generation (5G) network, a long-term evolution (LTE) network, a third generation (3G) network, a code division multiple access (CDMA) network, etc.), a public land mobile network (PLMN), a local area network (LAN), a wide area network (WAN), a metropolitan area network (MAN), a telephone network (e.g., the Public Switched Telephone Network (PSTN)), a private network, an ad hoc network, an intranet, the Internet, a fiber optic-based network, or the like, and/or a combination of these or other types of networks. Additionally or alternatively, the one or more networks may include a virtual network, which may include one or more physical network components (e.g., Ethernet, WiFi module, telecommunication network hardware, etc.) with one or more virtualized network functions (e.g., a control area network (CAN) bus, etc.) implemented therein. According to embodiments, communication and interoperation among the software abstraction layer 110 (or one or more components included therein), the components 120 and the UEs 130 may be performed via Over-the-Air (OTA).

In view of the above, example embodiments of the present disclosure provide a system (and a method for utilizing the same) for enabling multiple users to design or create an intended virtual vehicle network and simulation environment for managing (e.g., developing, sharing, testing, evaluating, etc.) components of the virtual vehicle network in the intended manner.

FIG. 2 illustrates a block diagram of example components of a components management system 200, according to one or more embodiments. System 200 may corresponds to the system 110-1 described above with reference to FIG. 1, thus the features described herein with reference to systems 110-1 and 200 may be applicable to one another, unless being explicitly described otherwise.

As illustrated in FIG. 2, the components management system 200 may include at least one communication interface 210, at least one storage 220, and at least one processor 230, although it can be understood that the components management system 200 may include more or less components than as illustrated, and/or the components included therein may be arranged in any a manner different from as illustrated, without departing from the scope of the present disclosure.

The communication interface 210 may include a transceiver-like component (e.g., a transceiver, a separate receiver and transmitter, etc.) that enables the components management system 200 (or one or more components included therein) to communicate with one or more components external to the components management system 200, such as via a wired connection, a wireless connection, or a combination of wired and wireless connections.

For instance, the communication interface 210 may couple the components management system 200 (or one or more components included therein) to a plurality of components (e.g., components 120-1 to 120-N in FIG. 1, etc.) and to a plurality of equipment (e.g., UEs 130-1 to 130-N, etc.) to thereby enable them to communicate and to interoperate with each. As another example, the communication interface 210 may enable the components of the components management system 200 to communicate with each other. For instance, the communication interface 210 may couple the storage 220 to the processor 230 to thereby enable them to communicate and to interoperate with each other.

According to embodiments, the communication interface 210 may include a hardware-based interface, such as a bus interface, an Ethernet interface, an optical interface, a coaxial interface, an infrared interface, a radio frequency (RF) interface, a universal serial bus (USB) interface, a Wi-Fi interface, a cellular network interface, a software interface, or the like. According to embodiments, communication interface 210 may include at least one controller area network (CAN) bus. Additionally or alternatively, the communication interface 210 may include a software-based interface, such as an application programming interface (API), a virtualized network interface (e.g., virtualized CAN bus, etc.), a programmatic interface, or the like. In some implementations, the communication interface 210 may act as a bus configuration tool which configured to utilize one or more APIs to interconnect components of the vehicle system (e.g., components 120) in a vehicle configuration specified by a user.

According to embodiments, the communication interface 210 may be configured to receive information from one or more components external to the components management system 200 and to provide the same to the processor 230 for further processing and/or to the storage 220 for storing. For instance, the communication interface 210 may fetch a real-time or near real-time status of a task, get logs associated with the task, monitor health status of a virtual vehicle (to be further discussed in below), enable one or more interactions among one or more users with the virtual vehicle and the testing environments, and the like.

The at least one storage 220 may include one or more storage mediums suitable for storing data, information, and/or computer-readable/computer-executable instructions therein. For instance, the storage 220 may store computer-readable instructions which, when being executed by one or more processors (e.g., processor 230), causes the one or more processors to perform one or more actions or operations described herein. According to embodiments, the storage 220 may include a random access memory (RAM), a read only memory (ROM), and/or another type of dynamic or static storage device (e.g., a flash memory, a magnetic memory, and/or an optical memory) that stores information and/or instructions for use by the processor 230.

Additionally or alternatively, the storage 220 may include a hard disk (e.g., a magnetic disk, an optical disk, a magneto-optic disk, and/or a solid state disk), a compact disc (CD), a digital versatile disc (DVD), a floppy disk, a cartridge, a magnetic tape, and/or another type of non-transitory computer-readable medium, along with a corresponding drive.

The at least one processor 230 may include one or more processors capable of being programmed to perform a function or an operation for managing components of a vehicle system. For instance, the processor 230 may be configured to execute computer-readable instructions stored in a storage medium (e.g., storage 220, etc.) to thereby perform one or more actions or one or more operations described herein.

According to embodiments, the processor 230 may be configured to receive (e.g., via the communication interface 210, etc.) one or more signals defining one or more instructions for performing one or more operations. Further, the processor 230 may be implemented in hardware, firmware, or a combination of hardware and software. The processor 230 may include a central processing unit (CPU), a graphics processing unit (GPU), an accelerated processing unit (APU), a microprocessor, a microcontroller, a digital signal processor (DSP), a field-programmable gate array (FPGA), an application-specific integrated circuit (ASIC), and/or another type of processing or computing component.

FIG. 3 illustrates a flow diagram of an example method 300 for managing components of a vehicle system, according to one or more embodiments. One or more operations of method 300 may be performed by at least one processor (e.g., processor 230) of the components management system of example embodiments.

In general, at least one user may utilize at least one UE to access the components management system, to select an intended vehicle model (with/without selection of a vehicle variant), and to select an intended operation for managing the components of the intended vehicle model. Accordingly, the components management system may be configured to build a virtual vehicle network representing the user-intended vehicle model (and the user-intended vehicle variant, if any) and user-intended simulation environment configuration, and to perform the user-intended operation for managing the user-intended component based thereon. The components management system may generate and present one or more graphical user interfaces (GUIs) to the at least one user to thereby interact with the at least one user in one or more operations. Further descriptions of example operations are provided in the following.

As illustrated in FIG. 3, at operation S310, the at least one processor of the components management system may be configured to receive, from at least one user, a first user input associated with a vehicle selection.

Specifically, the at least one processor may receive, from a user (via a UE associated therewith), a first user input associated with selection of a single vehicle model, a single variant of the single vehicle model, a plurality of vehicle models, a single variant of the plurality of vehicle models, a plurality of variants of the plurality of vehicle models, or a combination thereof. According to embodiments, the at least one processor may be configured to generate and present at least one GUI to the user, and may receive the first user input via determining one or more user interactions with the GUI. For instance, upon determining an access of the user (or the associated UE), the at least one processor may collect information of available vehicle models and vehicle variants, and may include said information in the GUI for the user selection. Accordingly, the user may interact with one or more interactive elements (e.g., interactable text, option list, button, etc.) to select the intended vehicle model(s) and/or the intended vehicle variant(s).

At operation S320, the at least one processor of the components management system may be configured to receive, from the user (via the associated UE), a second user input associated with configuration of simulation environment.

For instance, the at least one processor may receive a user selection or a user definition or selection on one or more operational models and/or one or more conditional models, such as user inputs of one or more vehicle dynamic parameters, one or more vehicle kinematic parameters, one or more vehicle control parameters, one or more road conditions, one or more weather conditions, one or more traffic conditions, one or more event parameters, and the like. According to embodiments, the at least one processor may generate and present at least one GUI to the user, and may receive the second user input via determining one or more user interactions with the GUI, in a similar manner of receiving the first user input (described above with reference to operation S310).

It can be understood that operations S310 and S320 described hereinabove may be performed in any suitable manner. For instance, operation S310 may be performed prior to operation S320, operation S310 may be performed after operation S320, operations S310 and S320 may be performed simultaneously, and the like.

Referring still to FIG. 3, upon receiving the first user input on the intended vehicle model(s)/variant(s) (at operation S310) and the second user input on the intended simulation environment configuration(s) (at operation S320), the method 300 may proceed to operation S330, at which the at least one processor of the components management system may be configured to determine, based on the first user input and the second user input, a plurality of hardware components and a plurality of software components associated with said user inputs.

For instance, the at least one processor may obtain, from one or more storage mediums (e.g., database 110-2, storage 220, etc.) based on the first user input, information associated with the user selected vehicle model(s) (and user selected variant(s), if any), such as vehicle specification, vehicle design information, and the like (may be referred to as “vehicle information” herein). Similarly, the at least one processor may obtain, from the one or more storage mediums based on the second user input, information associated with the user selected or the user-defined simulation environment configuration, such as user-selected or user defined operation models, user-selected or user defined conditional models, and the like.

Accordingly, the at least one processor may determine, based on the obtained vehicle information, the plurality of hardware components and the plurality of software components associated with the user selected vehicle model(s) (and user selected variant(s), if any). By way of example, based on determining that the user has selected a vehicle model of “Model A” and a vehicle variant of “Variant B”, the at least one processor may determine the hardware components information, such as type of hardware components (e.g., engine, sensor, actuator, physical ECU, etc.), version/serial number of the hardware components, vendor(s)/supplier(s) of the hardware components, and the like, which are associated with the specific combination of “Variant B of Model A”.

According to embodiments, the at least one processor may first determine the hardware components information of the user selected vehicle model(s), and may then filter out information which are not associated with the user selected vehicle variant(s). In some implementations, based on determining that the user has not selected a vehicle variant, the at least one processor may automatically select a default variant (e.g., most popular variant, variant with basic and essential features, variant associated with the user) associated with the user-selected vehicle model. In other implementations, based on determining that the user has not selected a vehicle variant, the at least one processor may simply obtain and maintain all hardware components information associated with the user-selected vehicle models (including hardware components information of all variants of the user-selected vehicle models).

It can be understood that the at least one processor may determine, based on the first user input and/or the second user input, the software components information, such as type of software components (e.g., OS, virtualized ECU, emulated ECU, operational models, conditional models, etc.), ID of the software components, user/user group (e.g., developer team, vendor, supplier, etc.) of the software components, information of hardware or devices hosting the software components, the programming codes or algorithms of the software components, and the like, in a similar as described above with relation to the example operations of obtaining the hardware component information.

Referring still to FIG. 3, upon determining the hardware components and software components associated with the user inputs (e.g., user selected vehicle model(s)/vehicle variant(s), user-defined simulation environment configuration, etc.) at operation S330, the method 300 may proceed to operation S340, at which the at least one processor of the components management system may be configured to build at least one virtual vehicle network based on the plurality of hardware components and the plurality of software components.

According to embodiments, the at least one processor may be configured to build the virtual vehicle network by interconnecting the plurality of hardware components and the plurality of software components.

In some implementations, the at least one processor may build at least one virtual vehicle replica, may build at least one simulation model, and may interconnect the at least one virtual vehicle replica to the at least one simulation model to thereby building the virtual vehicle network.

According to embodiments, the at least one processor may build the at least one simulation model by: obtaining, based on the second user input (received at operation S320), at least one least one operational model and at least one conditional model, and interconnecting the at least one operational model and the at least one conditional model to thereby building the at least one simulation model. The at least one simulation model defines the user-intended simulation environment configuration.

According to embodiments, the at least one processor may be configured to build the virtual vehicle replica by interconnecting the hardware components and the software components. Specifically, the at least one processor may obtain the connection configuration information (defined in vehicle specification or vehicle manual, etc.) of the user-selected vehicle mode(s), (and the user-selected vehicle variant(s), if any), and may create a virtual network based thereon. The term “virtual network”, in the context of virtual vehicle replica, may refer to a virtual representation of the connection among the software components and the hardware components of user-selected vehicle mode(s), (and the user-selected vehicle variant(s), if any), as if they are communicating across an actual vehicle according to the connection configuration information. Upon creating the virtual network, the at least one processor may interconnect the plurality of hardware components and the plurality of software components with the virtual network, to thereby create the virtual vehicle replica.

According to embodiments, the at least one processor may obtain the software components and may deploy said software components on appropriate device(s) or equipment. For instance, the software components (e.g., virtual ECU, emulated ECU, OS, operational models, conditional models, etc.) may be defined in the form of one or more containers, and the at least one processor may obtain said one or more containers, deploy the one or more containers on one or more devices, and configure the one or more devices to run the instances of the one or more containers. According to embodiments, the at least one processor may determine one or more resource requirements for deploying the one or more software components, may determine, from among a plurality of devices communicatively coupled to the components management system, one or more devices which satisfy the one or more resource requirements, and may deploy the one or more software components on the determined one or more devices. In this way, the at least one processor may dynamically deploy the software components to arbitrary device(s) which has the available resources for executing the software components, regardless of the geographical location(s) of the device(s) at which the software components are deployed.

According to embodiments, the at least one processor may determine whether or not the hardware components are available from among a plurality of hardware components communicatively coupled to the components management system, and may reserve the hardware components based on determining that said hardware components are available. In this way, the at least one processor may dynamically reserve arbitrary hardware components which satisfies the requirements, regardless of the geographical location at which the hardware components is deployed. Accordingly, the at least one processor may interconnect (with the virtual network, etc.) the device(s) deploying the software components and the reserved hardware components, to thereby building the virtual vehicle network.

According to embodiments, based on determining that a software component of the required software components and/or a hardware component of the required hardware components is unavailable, the at least one processor may determine whether or not a substitution component is available, and may utilize said substitution component when possible.

For instance, based on determining that a software component is unavailable (e.g., occurrence of software error, software maintenance, missing software files, etc.), the at least one processor may obtain a last known version (e.g., a backup version, etc.) of the software components, may obtain another software components which are associated therewith (e.g., software components with similar function, software components from similar user/user group, etc.), and/or may obtain a substitution component in any other suitable manner, and may then deploy the substitution component to the device(s) originally determined for deploying the unavailable software component. Alternatively or additionally, the at least one processor may determine whether or not a hardware component associated with the unavailable software component is available from among a plurality of hardware components communicatively coupled to the components management system, and may utilize the hardware component as substitution component when possible. For instance, based on determining that a virtual ECU is unavailable, the at least one processor may determine whether or not a hardware ECU having the same function/characteristic of the virtual ECU is available, and may utilize the hardware ECU as substitution component when possible.

Similarly, based on a hardware component is unavailable (hardware components fully reserved, insufficient resources for normal operations, etc.), the at least one processor may determine whether or not a software component associated with the unavailable hardware component is available from among a plurality of software components stored in the one or more storage mediums, and may utilize the software component as substitution component when possible. Alternatively or additionally, the at least one processor may determine and reserve another hardware component(s) which are associated with the unlivable hardware component (e.g., hardware component with similar function, software components from similar user/user group, etc.) as the substitution component.

According to embodiments, based on determining that a software component and/or a hardware component is unavailable and based on determining that no substitution component is available, the at least one processor may be configured to generate a temporary software model for simulating basic or essential functionalities of the unavailable software component and/or the unavailable hardware component.

To this end, at operation S340, the at least one processor may build a virtual vehicle network which satisfies the user-intended configurations and represents a user-intended vehicle system. Upon building the virtual vehicle network, the user may perform one or more operations for managing one or more components of the virtual vehicle network.

Specifically, at operation S350, the at least one processor of the components management system may be configured to receive, from the user, a third user input associated with at least one operation for managing at least a portion of the hardware components and the software components in the virtual vehicle. Said third user input may be received by the at least one processor via at least one GUI, in a similar manner of receiving the first user input (at operation S310) and the second user input (at operation S320).

Accordingly, at operation S360, the at least one processor of the components management system may be configured to perform, based on the third user input, the at least one operation for managing the portion of the hardware components and the software components. Descriptions of example operations for managing at least a portion of the hardware components and/or the software components in the virtual vehicle system are provided below with reference to the example use case in FIG. 4.

FIG. 4 illustrates an example system architecture 400 including a virtual vehicle network 420, according to one or more embodiments. The components management system 410, the UEs 430-1 and the database(s) 440 in FIG. 4 may be similar to the components management systems 110 and 200, the UEs 130, and the database(s) 110-2 in FIG. 1, respectively. Thus, redundant descriptions associated therewith may be omitted below for conciseness.

As illustrated in FIG. 4, the virtual vehicle network 420 may include at least one virtual vehicle replica 420-1 and at least one simulation model 420-2. The virtual vehicle network 420 may be generated by the components management system 410 (or the at least one processor associated therewith) in a similar manner described above with reference to FIG. 3.

At least a portion of the hardware components and/or the software components of the virtual vehicle network 420 may be located at different geographical locations, and/or may be associated with different users. For instance, a portion of the hardware components of the virtual vehicle replica 420-1 may be located a location(s) different from a device(s) deploying a portion the software components of the virtual vehicle replica 420-1, the device(s) deploying the portion the software components of the virtual vehicle replica 420-1 may be located at a location(s) different from devices deploying a portion of the simulation model 420-2, a portion of the hardware components may be managed by multiple users, and the like.

Further, the plurality of hardware components in the virtual vehicle network 420 may include a plurality of hardware in production (may be referred to as “production hardware” herein), a plurality of prototype hardware, or a combination thereof. Similarly, the plurality of software components comprises: a plurality of software in production (may be referred to as “production software” herein), a plurality of prototype software, a plurality of virtual hardware, or a combination thereof. Descriptions of examples of hardware components and software components are provided above with reference to FIG. 1 to FIG. 3, thus redundant descriptions associated therewith may be omitted below for conciseness.

Furthermore, although it is illustrated in FIG. 4 that the virtual vehicle network 420 includes one virtual vehicle replica and one simulation model, it can be understood that the at least one processor of the components management system 410 may be configured to generate a plurality of virtual vehicle replicas and/or a plurality of simulation models in one virtual vehicle network, without departing from the scope of the present disclosure. For instance, the at least one processor may, based on determining that the user has selected a plurality of vehicle models and/or a plurality of vehicle variants, generate a virtual vehicle network which includes a plurality of virtual vehicle replicas, each of which is associated with each of the plurality of vehicle models and/or the plurality of vehicle variants.

Upon building the virtual vehicle network 420, the at least one processor of the components management system 410 may assign a unique ID to the virtual vehicle network 420 and may store the configuration of the virtual vehicle network 420, along with the assigned ID, to the database(s) 440. According to embodiments, the virtual vehicle network 420 may be store in a form of configuration file which includes configuration information of the virtual vehicle network, such as information of the associated hardware components, information of the associated software components, information defining the interconnections and relationship between the hardware components and the software components, and the like.

To this end, the user may utilize the components management system 410 to perform one or more operations for managing the components of the virtual vehicle network 420. Said one or more operations may include: sharing at least a portion the virtual vehicle network 420, designing a vehicle by arranging the components of the virtual vehicle replica 420-1, designing a test scenario by arranging the components of the simulation model 420-2, and testing a software component in the virtual vehicle network. One or more of aforesaid operations may be performed via OTA.

According to embodiments, the user who has built a virtual vehicle network (may be referred to as “first user” herein) may utilize the components management system 410 to share the built virtual vehicle network (or one or more components included therein) with another user (may be referred to as “second user” herein). The first user and the second user may be located at different geographical locations and/or may be from different background (e.g., the first user may from a developer team and the second user may from a testing team, the first user may from vehicle manufacturer and the second user may from a vendor/supplier, etc.).

For instance, upon building the virtual vehicle network 420, the at least one processor may receive, from the first user, a user input (e.g., third user input described above with reference to operation S350, etc.) for specifying a sharing setting of the built virtual vehicle network. The sharing setting may include: user/user group to which the virtual vehicle network (or the component(s) therein) should be shared, component(s) of the virtual vehicle network which should be shared (e.g., full virtual vehicle network, virtual vehicle replica only, a portion of the simulation model, etc.), type of sharing (e.g., temporary, permanent, etc.), privileges of shared components (e.g., view only, view and edit, copy and share, full privileges, etc.), and the like. Accordingly, the at least one processor may retrieve the configuration file of the virtual vehicle network, update the configuration file to include the user specified sharing setting, and store the updated configuration file to the database(s) 440.

Accordingly, the second user may utilize the components management system 410 to perform one or more operations for managing one or more components associated with the virtual vehicle network 420. For instance, assuming that the first user has specified the sharing setting to share the whole virtual vehicle network 420 with full privileges to the second user, whenever the second user access the components management system 410, the GUI generated and presented by the at least one processor of the components management system 410 may include the virtual vehicle network 420 as an selectable option for management. Accordingly, the second user may interact with the GUI for selecting the virtual vehicle network (or one or more components included therein) for management.

According to embodiments, the first user and the second user may simultaneously access the components management system 410 and may separately manage the components of the virtual vehicle network 420. For instance, the first user would like to create a new software feature for the virtual vehicle replica 420-1, while the second user would like to run a testing on a software component of the virtual vehicle 420-1, the first user and the second user may do so without interfering each other. Specifically, whenever the first user and the second user would like to perform the management operation, said users may select the desired virtual vehicle network and may opt to perform the management operation independently (e.g., selecting a tick box of “manage independently” on the presented GUI, etc.).

Accordingly, the components management system 410 may simply obtain the configuration file of the selected virtual vehicle network, and may build the virtual vehicle network for the first user and the second user by interconnecting hardware components and software components separated from each other. For instance, the hardware components of the virtual vehicle network being managed by the first user may be located at a location different from the hardware components of the virtual vehicle network being managed by the second user, and the like. In this way, multiple users may simultaneously and independently manage the same virtual vehicle network, without interfering each other. To this end, the multiple users only need to interact with the abstract level information (e.g., configuration of virtual vehicle network, components of virtual vehicle replica, etc.), without requiring to know the exact locations at which the components are deployed and located.

According to embodiments, the first user and the second user may simultaneously access the components management system 410 and may collaboratively manage the components of the virtual vehicle network 420. For instance, the first user would like to perform a testing on a newly developed software component (e.g., virtual ECU, etc.) of the virtual vehicle replica 420-1, while the second user would like to monitor the testing process and to adjust the simulation model 420-2 throughout the testing process so as to build a simulation model suitable for the virtual vehicle replica 420-1 with the newly developed software components integrated therein.

In this example use case, the first user may provide the newly developed software component to the components management system 410 (via at least one GUI provided by the components management system 410, etc.) and to specify the configuration of the newly developed software component (e.g., which hardware component/software component it should be connected to, etc.) and the at least one processor of the components management system 410 may update the configuration file of the virtual vehicle replica 420-1 to include the configuration of the newly developed software component, and at the meantime may store the newly developed software component (e.g., programming codes, algorithms, containers, etc.) to the database(s) 440.

Accordingly, upon receiving a trigger for performing the testing on the newly developed software component (e.g., upon determining a user interaction with a specific interactive element, such as a “Start Testing” button in at least one presented GUI, upon determining that a current time is within a period of time from a scheduled testing time, etc.), the at least one processor may retrieve, from the database(s) 440, the updated configuration file of the virtual vehicle network and may build the virtual vehicle network based on the updated configuration file.

Subsequently, the at least one processor may determine one or more test environments (e.g., Hardware-in-the-Loop (HIL) test environment, Software-in-the-Loop (SIL) test environment, etc.) associated with the user intended testing, and may perform the testing on the virtual vehicle network 420 based thereon. For instance, the at least one processor may perform testing on hardware components of the virtual vehicle replica 420-1 on one or more HIL test environments based on the simulation model 420-2 to obtain a first portion of testing result, may perform testing on software components of the virtual vehicle replica 420-1 on one or more SIL test environments based on the simulation model 420-2 to obtain a second portion of testing result, and may combine the first portion and the second portion of the testing result to form a complete testing result representing a testing result of the virtual vehicle replica in the simulation environment configured by the simulation model 420-2 as a whole.

Upon obtaining the testing result, the at least one processor may store the testing result in the database(s) 440, and may update the GUI presented to the second user to present the testing result, in real-time or near real-time. Accordingly, the second user may adjust the components of the simulation model 420-2 based on the testing result. The at least one processor of the components management system 410 may update the configuration file of the virtual vehicle network 420 to include the information of the adjusted simulation model 420-2. In this regard, if the testing operation performed by the first user is still on-going, the at least one processor may update, based on the updated configuration file, the virtual vehicle network 420 to include the latest configuration of the simulation model 420-2. Accordingly, the testing operation performing by the first user may be continued, based on the latest configuration of the simulation model 420-2 provided by the second user.

In view of the above, example embodiments of present disclosure simultaneously receive latest information from multiple users and store/update said latest information in the database(s) 440, so as to allow the information to be synchronized. Accordingly, multiple users may simultaneously and collaboratively manage components of the virtual vehicle network in an effective and efficient manner.

According to another embodiments, multiple users may simultaneously access the component management system 440, while the management operation are being performed in a sequential manner. For instance, the at least one processor of the components management system may simultaneously receive, from multiple UEs, requests for performing management operations on a virtual vehicle network. In this regard, the at least one processor may be configured to queue or prioritize the requests based on, for example, time to run, cost, efficiency, complexity, user priority, impact level, and urgency level.

It can be understood that the example embodiments described above are merely a portion of possible use cases, and the scope of the present disclosure should not be limited thereto. For instance, the components management system of example embodiments may be appropriately utilized in any suitable manner to manage any component(s) of any suitable vehicle system, without departing from the scope of the present disclosure. For instance, according to embodiments, the components management system of example embodiments may be implemented with, or may be configured to interoperate with a system equipping, one or more machine learning (ML) or artificial intelligence (AI) algorithms for components management.

To this end, example embodiments of the present disclosure provide a components management systems that can be utilized to build a virtual vehicle network that can be accessed remotely by multiple users from multiple locations, for purposes of component management, such as software components development, testing, validation, and the like, for one or more vehicle models and/or one or more vehicle variants via a software abstraction layer. The multiple users may effectively and efficiently manage the components by interacting with the virtual vehicle network, regardless of the exact underlying hardware components and devices for deploying the software components. Thus, example embodiments of the present disclosure remove the need to domain expertise on the underlying components.

Further, the virtual vehicle network built and managed by the components management system of example embodiments may provide a high fidelity communication infrastructure between hardware components and software components. For instance, the virtual vehicle network consist of variable components, such as hardware components and software components in production, prototype hardware components and software components, and virtual hardware components and software components. This takes advantage of the high fidelity of production hardware and the cost effectiveness of emulated or virtualized software components in a single hybrid environment.

Furthermore, the management processes (e.g., development process, testing process, etc.), and the components involved therein (e.g., software code, etc.) can be traced throughout the processes and can be effectively shared among multiple users, for purposes of safety, royalty accounting, billing management, and the like.

Ultimately, example embodiments of the present disclosure enable efficient and effective management of components of a vehicle system, thereby addressing the problems in the related art as described above.

It is contemplated that features, advantages, and significances of example embodiments described hereinabove are merely a portion of the present disclosure, and are not intended to be exhaustive or to limit the scope of the present disclosure. Further, tt is understood that the specific order or hierarchy of blocks in the processes/flowcharts disclosed herein is an illustration of example approaches. Based upon design preferences, it is understood that the specific order or hierarchy of blocks in the processes/flowcharts may be rearranged. Further, some blocks may be combined or omitted. The accompanying method claims present elements of the various blocks in a sample order, and are not meant to be limited to the specific order or hierarchy presented.

Some embodiments may relate to a system, a method, and/or a computer-readable medium at any possible technical detail level of integration. Further, as described hereinabove, one or more of the above components described above may be implemented as instructions stored on a computer readable medium and executable by at least one processor (and/or may include at least one processor). The computer-readable medium may include a computer-readable non-transitory storage medium (or media) having computer-readable program instructions thereon for causing a processor to carry out operations.

The computer readable storage medium can be a tangible device that can retain and store instructions for use by an instruction execution device. The computer-readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer-readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer-readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program code/instructions for carrying out operations may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object-oriented programming languages such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects or operations.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or another device to cause a series of operational steps to be performed on the computer, other programmable apparatus or other device to produce a computer-implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer-readable media according to various embodiments. In this regard, each block in the flowchart or block diagrams may represent a module, segment, or portion of instructions, which comprises one or more executable instructions for implementing the specified logical function(s). The method, computer system, and computer-readable medium may include additional blocks, fewer blocks, different blocks, or differently arranged blocks than those depicted in the Figures. In some alternative implementations, the functions noted in the blocks may occur out of the order noted in the Figures. For example, two blocks shown in succession may, in fact, be executed concurrently or substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code-it being understood that software and hardware may be designed to implement the systems and/or methods based on the description herein.

What is claimed is:

1. A method for managing components of a vehicle system, the method being implemented by at least one processor of a system and comprising:
receiving, from a first user, a first user input associated with selection of at least one of: a single vehicle model, a single variant of the single vehicle model, a plurality of vehicle models, a single variant of the plurality of vehicle models, and a plurality of variants of the plurality of vehicle models;
receiving, from the first user, a second user input associated with configuration of a simulation environment;
determining, based on the first user input and the second user input, a plurality of hardware components and a plurality of software components associated with the first user input and the second user input;
building a virtual vehicle network by interconnecting the plurality of hardware components and the plurality of software components, wherein the virtual vehicle network comprises the interconnection of the components of the vehicle system;
receiving, from the first user, a third user input associated with a first operation for managing a first portion of the hardware components and the software components in the virtual vehicle network; and
performing, based on the third user input, the first operation on the virtual vehicle network to manage the first portion of the hardware components and the software components.

2. The method according to claim 1, further comprising:
receiving, from a second user, a fourth user input for selecting the virtual vehicle network;
receiving, from the second user, a fifth user input associated with a second operation for managing a second portion of the hardware components and the software components in the virtual vehicle network; and
performing, based on the fifth user input, the second operation on the virtual vehicle network to manage the second portion of the hardware components and the software components,
wherein the second operation is different from the first operation, and wherein the second portion is different from the first portion.

3. The method according to claim 1, wherein at least a portion of: the plurality of hardware components, the plurality of software components, or a combination thereof, are located at different geographical locations.

4. The method according to claim 1, wherein at least a portion of: the plurality of hardware components, the plurality of software components, or a combination thereof, are associated with users different from the first user.

5. The method according to claim 1, wherein the plurality of hardware components comprises: a plurality of production hardware, a plurality of prototype hardware, or a combination thereof; and wherein the plurality of software components comprises: a plurality of production software, a plurality of prototype software, a plurality of virtual hardware, or a combination thereof.

6. The method according to claim 3, wherein at least a portion of the plurality of hardware components and at least a portion of the plurality of software components are located at different geographical locations, and wherein the building the virtual vehicle network comprises:
building, based on the plurality of hardware components and the plurality of software components located at different geographical locations, at least one virtual vehicle replica;
building at least one simulation model; and
interconnecting the at least one virtual vehicle replica to the at least one simulation model to build the virtual vehicle network.

7. The method according to claim 6, wherein the building the at least one virtual vehicle replica comprises:
obtaining a connection configuration information;
creating, based on the connection configuration information, a virtual network; and
interconnecting the plurality of hardware components and the plurality of software components located at different geographical locations with the virtual network.

8. The method according to claim 7, wherein the interconnecting the plurality of hardware components and the plurality of software components comprises:
deploying the plurality of software components in one or more devices communicatively coupled to the system;
reserving the plurality of hardware components; and
interconnecting the one or more devices and the reserved hardware components.

9. The method according to claim 6, wherein the building the at least one simulation model comprises:
obtaining, based on the second user input, at least one operational model and at least one conditional model; and
interconnecting the at least one operational model and the at least one conditional model to build the at least one simulation model,
wherein the at least operational model comprises information defining vehicle dynamics, vehicle kinematics, and vehicle control, and wherein the at least one conditional model comprises information defining a road condition, a weather condition, a traffic condition, and an event.

10. The method according to claim 6, wherein the performing the one or more actions comprises performing at least one of:
sharing, to one or more users different from the first user, at least a portion the virtual vehicle network;
designing, by arranging the at least one virtual vehicle replica, a vehicle;
designing, by arranging the at least one simulation model, a test scenario; and
testing a software component in the virtual vehicle network.

11. A system for managing components of a vehicle system, the system comprising:
a memory storage storing computer-executable instructions; and
at least one processor communicatively coupled to the memory storage, wherein the at least one processor is configured to execute the instructions to:
receive, from a first user, a first user input associated with selection of at least one of: a single vehicle model, a single variant of the single vehicle model, a plurality of vehicle models, a single variant of the plurality of vehicle models, and a plurality of variants of the plurality of vehicle models;
receive, from the first user, a second user input associated with configuration of a simulation environment;
determine, based on the first user input and the second user input, a plurality of hardware components and a plurality of software components associated with the first user input and the second user input;
build a virtual vehicle network by interconnecting the plurality of hardware components and the plurality of software components, wherein the virtual vehicle network comprises the interconnection of the components of the vehicle system;
receive, from the first user, a third user input associated with a first operation for managing a first portion of the hardware components and the software components in the virtual vehicle network; and
perform, based on the third user input, the first operation on the virtual vehicle network to manage the first portion of the hardware components and the software components.

12. The system according to claim 11, wherein the at least one processor is further configured to execute the instructions to:
receive, from a second user, a fourth user input for selecting the virtual vehicle network;
receive, from the second user, a fifth user input associated with a second operation for managing a second portion of the hardware components and the software components in the virtual vehicle network; and
perform, based on the fifth user input, the second operation on the virtual vehicle network to manage the second portion of the hardware components and the software components,
wherein the second operation is different from the first operation, and wherein the second portion is different from the first portion.

13. The system according to claim 11, wherein at least a portion of: the plurality of hardware components, the plurality of software components, or a combination thereof, are located at different geographical locations.

14. The system according to claim 11, wherein at least a portion of: the plurality of hardware components, the plurality of software components, or a combination thereof, are associated with users different from the first user.

15. The system according to claim 11, wherein the plurality of hardware components comprises: a plurality of production hardware, a plurality of prototype hardware, or a combination thereof; and wherein the plurality of software components comprises: a plurality of production software, a plurality of prototype software, a plurality of virtual hardware, or a combination thereof.

16. The system according to claim 3, wherein at least a portion of the plurality of hardware components and at least a portion of the plurality of software components are located at different geographical locations, and wherein the at least one processor is configured to execute the instructions to build the virtual vehicle network by:
building, based on the plurality of hardware components and the plurality of software components located at different geographical locations, at least one virtual vehicle replica;
building at least one simulation model; and
interconnecting the at least one virtual vehicle replica to the at least one simulation model to build the virtual vehicle network.

17. The system according to claim 16, wherein the at least one processor is configured to execute the instructions to build the at least one virtual vehicle replica by:
obtaining a connection configuration information;
creating, based on the connection configuration information, a virtual network; and
interconnecting the plurality of hardware components and the plurality of software components located at different geographical locations with the virtual network.

18. The system according to claim 17, wherein the at least one processor is configured to execute the instructions to interconnect the plurality of hardware components and the plurality of software components by:
deploying the plurality of software components in one or more devices communicatively coupled to the system;
reserving the plurality of hardware components; and
interconnecting the one or more devices and the reserved hardware components.

19. The system according to claim 16, wherein the at least one processor is configured to execute the instructions to build the at least one simulation model by:
obtaining, based on the second user input, at least one operational model and at least one conditional model; and
interconnecting the at least one operational model and the at least one conditional model to build the at least one simulation model,
wherein the at least operational model comprises information defining vehicle dynamics, vehicle kinematics, and vehicle control, and wherein the at least one conditional model comprises information defining a road condition, a weather condition, a traffic condition, and an event.

20. The system according to claim 16, wherein the at least one processor is configured to execute the instructions to perform the one or more actions by performing at least one of:
sharing, to one or more users different from the first user, at least a portion the virtual vehicle network;
designing, by arranging the at least one virtual vehicle replica, a vehicle;
designing, by arranging the at least one simulation model, a test scenario; and
testing a software component in the virtual vehicle network.
